(19) United States
(12) Patent Application Publication
(10) Pub. No.: US 2021/0324235 A1
(43) Pub. Date: Oct. 21, 2021

(54) COMPOSITION FOR FORMING SILICA LAYER, SILICA LAYER FORMED THEREFROM, AND ELECTRONIC DEVICE INCLUDING SILICA LAYER

(71) Applicant: Samsung SDI Co., Ltd., Yongin-si (KR)

(72) Inventors: Wanhee LIM, Suwon-si (KR); Hyeonsu Jo, Suwon-si (KR); Byeonggyu Hwang, Suwion-si (KR); Taeksoo Kwak, Suwon-si (KR); Jin-Hee Bae, Suwon-si (KR); Seungwoo Jang, Suwon-si (KR)

(73) Assignee: Samsung SDI Co., Ltd., Yongin-si (KR)

(21) Appl. No.: 17/224,363

(22) Filed: Apr. 7, 2021

(30) Foreign Application Priority Data
Apr. 16, 2020 (KR) 10-2020-0046179

(51) Int. Cl. C09D 183/16; B05D 1/00; C08G 77/62; B05D 3/10

(52) U.S. Cl. CPC C09D 183/16; B05D 1/005; B05D 2518/12; B05D 3/108; C08G 77/62

(57) ABSTRACT

Provided is a composition for forming a silica layer including a silicon-containing polymer, and a solvent, wherein the silicon-containing polymer has a weight average molecular weight (Mw) of 8,000 g/mol to 15,000 g/mol, and wherein a content of nitrogen atoms of the silicon-containing polymer measured by a kjeldahl titration method is 25 wt % to 30 wt % based on a total weight of the silicon-containing polymer.

### CROSS-REFERENCE TO THE RELATED APPLICATION

This application claims priority to Korean Patent Application No. 10-2020-0046179 filed in the Korean Intellectual Property Office on Apr. 16, 2020, the entirety of which is incorporated herein by reference.

### BACKGROUND

### 1. Field

Example embodiments of the present disclosure relate to a composition for forming a silica layer, a silica layer manufactured using the composition, and an electronic device including the silica layer.

### 2. Description of Related Art

As semiconductor technology is increasingly developed, there have been continuous research on forming highly-integrated and faster semiconductor memory cells that have improved performance and integrate smaller semi-conductor chips. However, requirements of the high integration of a semiconductor may narrow a distance among wires and thus, bring about a RC delay, a cross-talk, deterioration of a response speed, and the like, which may cause a problem in terms of interconnection of the semiconductor. In order to solve this problem, proper separation between devices is required.

Accordingly, a silica layer formed of a silicon-containing material is widely used as an interlayer insulating layer, a planarization layer, a passivation layer an inter-element isolation insulating layer and the like for semiconductor devices for proper separation between devices. The silica layer is used not only as a semiconductor device, but also as a protective layer for a display device, an insulating layer, and the like.

In semiconductor devices of 40 nm or less such as liquid crystals and the like, high integration of patterns is intensified, and according to this intensifying integration density, a silica layer formed in flowable chemical vapor deposition (F-CVD) or coating is used as an insulation layer in which narrow patterns are filled. In order to form a silica layer having this insulation property, a coating solution containing inorganic polysilazane is used for spin-on dielectric (SOD). However, when the inorganic polysilazane solution is spin-coated and cured on a pattern wafer, there may be a problem of deteriorating etch resistance of the silica layer.

### SUMMARY

One or more example embodiments provide a composition for forming a silica layer having a significantly improved etch resistance when forming a silica layer.

One or more example embodiments also provide a silica layer manufactured by using the composition for forming a silica layer.

One or more example embodiments also provide an electronic device including the silica layer.

According to an aspect of an example embodiment, there is provided a composition for forming a silica layer including a silicon-containing polymer, and a solvent, wherein the silicon-containing polymer has a weight average molecular weight (Mw) of 8,000 g/mol to 15,000 g/mol, and wherein a content of nitrogen atoms of the silicon-containing polymer measured by a kjeldahl titration method is 25 wt % to 30 wt % based on a total weight of the silicon-containing polymer.

The silicon-containing polymer may include polysilazane, polysiloxazane, or a combination thereof.

The silicon-containing polymer may be perhydropolysilazane (PHPS).

The Mw of the silicon-containing polymer may be 8,000 g/mol to 12,000 g/mol.

The content of nitrogen atoms of the silicon-containing polymer measured by the kjeldahl titration method may be 27 wt % to 29 wt % based on the total weight of the silicon-containing polymer.

An amount of the silicon-containing polymer included may be 0.1 wt % to 30 wt % based on a total amount of the composition for forming the silica layer.

The solvent may include benzene, toluene, xylene, ethylbenzene, diethylbenzene, trimethylbenzene, triethylbenzene, cyclohexane, cyclohexene, decahydro naphthalene, dipentene, pentane, hexane, heptane, octane, nonane, decane, ethylcyclohexane, methylcyclohexane, cyclohexane, cyclohexene, p-menthane, dipropylether, dibutylether, anisole, butyl acetate, amyl acetate, methylisobutylketone, or a combination thereof.

According to another aspect of an example embodiment, there is provided a silica layer formed by a composition, the composition including a silicon-containing polymer, and a solvent, wherein the silicon-containing polymer has a weight average molecular weight (Mw) of 8,000 g/mol to 15,000 g/mol, and wherein a content of nitrogen atoms of the silicon-containing polymer measured by a kjeldahl titration method is 25 wt % to 30 wt % based on a total weight of the silicon-containing polymer.

The silicon-containing polymer may include polysilazane, polysiloxazane, or a combination thereof.

The silicon-containing polymer may be perhydropolysilazane (PHPS).

The Mw of the silicon-containing polymer may be 8,000 g/mol to 12,000 g/mol.

The content of nitrogen atoms of the silicon-containing polymer measured by the kjeldahl titration method may be 27 wt % to 29 wt % based on the total weight of the silicon-containing polymer.

An amount of the silicon-containing polymer included may be 0.1 wt % to 30 wt % based on a total amount of the composition for forming the silica layer.

The solvent may include benzene, toluene, xylene, ethylbenzene, diethylbenzene, trimethylbenzene, triethylbenzene, cyclohexane, cyclohexene, decahydro naphthalene, dipentene, pentane, hexane, heptane, octane, nonane, decane, ethylcyclohexane, methylcyclohexane, cyclohexane, cyclohexene, p-menthane, dipropylether, dibutylether, anisole, butyl acetate, amyl acetate, methylisobutylketone, or a combination thereof.

According to another aspect of an example embodiment, there is provided an electronic device including a silica layer formed based on a composition, wherein the composition includes a silicon-containing polymer, and a solvent, wherein the silicon-containing polymer has a weight average molecular weight (Mw) of 8,000 g/mol to 15,000 g/mol, and wherein a content of nitrogen atoms of the silicon-containing polymer measured by a kjeldahl titration method is 25 wt % to 30 wt % based on a total weight of the silicon-containing polymer.

The silicon-containing polymer may include polysilazane, polysiloxazane, or a combination thereof.

The silicon-containing polymer may be perhydropolysilazane (PHPS).

The Mw of the silicon-containing polymer may be 8,000 g/mol to 12,000 g/mol.

The content of nitrogen atoms of the silicon-containing polymer measured by the kjeldahl titration method may be 27 wt % to 29 wt % based on the total weight of the silicon-containing polymer.

An amount of the silicon-containing polymer included may be 0.1 wt % to 30 wt % based on a total amount of the composition for forming the silica layer.

### DETAILED DESCRIPTION OF THE EMBODIMENTS

Hereinafter, example embodiments are described in detail. However, these example embodiments are exemplary, the present disclosure is not limited thereto and defined by the scope of claims.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, when a definition is not otherwise provided, the term “substituted” refers to replacement of hydrogen of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, an alkyl group, a C2 to C16 alkenyl group, a C2 to C16 alkynyl group, an aryl group, a C7 to C13 arylalkyl group, a C1 to C4 oxyalkyl group, a C1 to C20 heteroalkyl group, a C3 to C20 heteroarylalkyl group, a cycloalkyl group, a C3 to C15 cycloalkenyl group, a C6 to C15 cycloalkynyl group, a heterocycloalkyl group, and a combination thereof.

As used herein, when a definition is not otherwise provided, the term “hetero” refers to one including 1 to 3 heteroatoms selected from N, O, S, and P.

In the present specification, when a definition is not otherwise provided, “*” refers to a linking portion between the same or different atoms, or chemical formulae.

Hereinafter, a composition for forming a silica layer according to an example embodiment is described.

A composition for forming a silica layer according to an example embodiment includes a silicon-containing polymer and a solvent. The silicon-containing polymer has a weight average molecular weight (Mw) of about 8,000 g/mol to about 15,000 g/mol, and a content of nitrogen atoms of the silicon-containing polymer measured by a kjeldahl titration method is about 25 wt % to about 30 wt % based on a total weight of the silicon-containing polymer.

The silicon-containing polymer is a polymer containing silicon (Si) in the main chain, and may include polysilazane, polysiloxazane, or a combination thereof, for example, perhydropolysilazane (PHPS).

In an example embodiment, the silicon-containing polymer may include a hydrogenated polysilazane including a moiety represented by Chemical Formula 1.

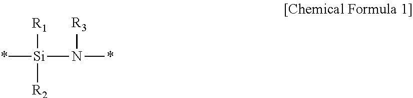

In Chemical Formula 1, R₁ to R₃ are independently hydrogen, a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkenyl group, a substituted or unsubstituted alkoxy group, a carboxyl group, an aldehyde group, a hydroxy group, or a combination thereof, and“*” is a linking point.

The hydrogenated polysilazane may be prepared by various methods including, for example, reacting halosilane and ammonia.

The silicon-containing polymer may be a hydrogenated polysiloxane further including a moiety represented by Chemical Formula 2 in addition to the moiety represented by Chemical Formula 1.

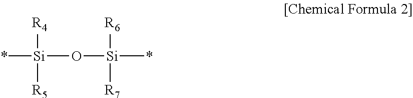

In Chemical Formula 2, R₄ to R₇ are independently hydrogen, a substituted or unsubstituted C1 to C30 alkyl group, a substituted or unsubstituted C3 to C30 cycloalkyl group, a substituted or unsubstituted C6 to C30 aryl group, a substituted or unsubstituted C7 to C30 arylalkyl group, a substituted or unsubstituted C1 to C30 heteroalkyl group, a substituted or unsubstituted C2 to C30 heterocycloalkyl group, a substituted or unsubstituted C2 to C30 alkenyl group, a substituted or unsubstituted alkoxy group, a carboxyl group, an aldehyde group, a hydroxy group, or a combination thereof, and “*” is a linking point.

When the silicon-containing polymer further includes a moiety of Chemical Formula 2, the silicon-containing polymer may be a hydrogenated polysiloxane further including a silicon-oxygen-silicon (Si—O—Si) bond moiety in addition to a silicon-nitrogen (Si—N) bond moiety in the structure. When such a hydrogenated polysiloxane is cured by heat treatment, the silicon-oxygen-silicon (Si—O—Si) bond moiety relieves stress, thereby reducing shrinkage of the silica layer manufactured from the hydrogenated polysiloxane.

Further, the polysilazane or polysiloxane may include a moiety represented by Chemical Formula 3 at the terminal end.

*—SiH₃ [Chemical Formula 3]

The moiety represented by Chemical Formula 3 has a structure in which the terminal end is capped with hydrogen, and may be included in an amount of about 15 wt % to about 35 wt % based on a total amount of Si—H bonds in the polysilazane or polysiloxane structure. When the moiety of Chemical Formula 3 is included in the above range in the polysilazane or polysiloxane structure, an oxidation reaction may occur sufficiently during the heat treatment and during heat treatment, the SiH₃ moiety becomes SiH₄ to prevent scattering, thereby preventing shrinkage, and preventing cracks from occurring in the silica layer manufactured therefrom.

The polysilazane, polysiloxane, or perhydropolysilazane solution (composition for forming a silica layer) which may be used as the silicon-containing polymer is coated on a patterned wafer using a spin-on coating method and then cured.

When the composition for forming a silica layer is coated on a wafer using a spin-on coating method and cured, compared with the related F-CVD method, when filled in a trench having various depths and widths, the etch resistance of the formed silica layer may be deteriorated.

The silicon-containing polymer according to an example embodiment has a weight average molecular weight in a specific range, and a nitrogen atom in the silicon-containing polymer measured by a kjeldahl titration method is included in a specific content range, thereby solving the problem of deteriorating the etch resistance of the silica layer manufactured from the composition for forming a silica layer including the silicon-containing polymer.

When a layer is formed by coating a composition for forming a silica layer through spin-on coating, and the layer is heat-treated to cure the layer and manufacture a silica layer, hydrolysis of the Si—N bond of the silicon-containing polymer in the layer occurs, and as a result, Si—O bonds (SiO₂) are formed in the silicon-containing polymer. Herein, when the content of nitrogen (N) atoms in the silicon-containing polymer increases beyond a certain range, a rate at which Si—N bonds are converted to Si—O bonds (SiO₂) slows down, and accordingly, as curing of the upper portion of the layer is delayed, curing may evenly occur to the bottom of the silica layer. As a result, the etch resistance of the manufactured silica layer may be improved.

The silicon-containing polymer constituting the composition for forming a silica layer may control the weight average molecular weight by varying the synthesis conditions, and the etch resistance of the composition for forming a silica layer including the same may be improved by controlling a distribution of the weight average molecular weight of the silicon-containing polymer.

According to example embodiments, a weight average molecular weight of the silicon-containing polymer may be greater than or equal to about 8,000 g/mol, greater than or equal to about 8,200 g/mol, greater than or equal to about 8,500 g/mol, greater than or equal to about 8,700 g/mol, greater than or equal to about 9,000 g/mol, greater than or equal to about 9,200 g/mol, greater than or equal to about 9,400 g/mol, greater than or equal to about 9,500 g/mol, greater than or equal to about 9,700 g/mol, greater than or equal to about 10,000 g/mol, greater than or equal to about 10,200 g/mol, greater than or equal to about 10,500 g/mol, greater than or equal to about 10,700 g/mol, greater than or equal to about 11,000 g/mol, greater than or equal to about 11,200 g/mol, greater than or equal to about 11,500 g/mol, greater than or equal to about 11,700 g/mol, or greater than or equal to about or 11,900 g/mol, and the weight average molecular weight of the silicon-containing polymer may be less than or equal to about 15,000 g/mol, less than or equal to about 14,700 g/mol, less than or equal to about 14,500 g/mol, less than or equal to about 14,200 g/mol, less than or equal to about 14,000 g/mol, less than or equal to about 13,700 g/mol, less than or equal to about 13,500 g/mol, less than or equal to about 13,200 g/mol, less than or equal to about 13,000 g/mol, less than or equal to about 12,700 g/mol, less than or equal to about 12,500 g/mol, less than or equal to about 12,200 g/mol, or less than or equal to about 12,000 g/mol, but is not limited thereto.

When the weight average molecular weight of the silicon-containing polymer is less than about 8,000 g/mol, mechanical and chemical properties of the manufactured silica layer may be deteriorated, while when the weight average molecular weight of the silicon-containing polymer exceeds about 15,000 g/mol, gelation of the silicon-containing polymer may occur in contact with moisture. When the weight average molecular weight of the silicon-containing polymer satisfies the above described range according to example embodiments, the composition for forming a silica layer including the silicon-containing polymer may improve the etch resistance of the silica layer manufactured therefrom.

According to example embodiments, the content of nitrogen atoms of the silicon-containing polymer measured by a kjeldahl titration method may be about 25 wt % to about 30 wt %. For example, the content of nitrogen atoms of the silicon-containing polymer measured by a kjeldahl titration method may be about 25 wt % to about 29 wt %, about 25 wt % to about 28 wt %, about 25 wt % to about 27 wt %, about 25 wt % to about 26 wt %, about 26 wt % to about 30 wt %, about 27 wt % to about 30 wt %, about 28 wt % to about 30 wt %, about 29 wt % to about 30 wt %, about 26 wt % to about 29 wt %, about 26 wt % to about 28 wt %, about 27 wt % to about 29 wt %, or about 27 wt % to about 28 wt % based on the total weight of the silicon-containing polymer, but is not limited thereto. When the content of nitrogen atoms of the silicon-containing polymer is less than about 25 wt % based on the total weight of the silicon-containing polymer, a rate of converting Si—N bonds in the silicon-containing polymer into Si—O bonds may not be slowed down. Accordingly, the upper portion of the layer including the silicon-containing polymer may have more heat treatment effects and thus may be cured faster than the lower portion. Thus, an etch resistance may not be improved due to the curing rate difference in the upper and lower portions of the silica layer.

When the content of nitrogen atoms of the silicon-containing polymer is greater than about 30 wt % based on the total weight of the silicon-containing polymer, the rate of converting the Si—N bonds into the Si—O bonds in the silicon-containing polymer may be overall significantly slowed down in both of the upper and lower portions of the silica layer despite the heat treatment, and accordingly, efficiency of forming the silica layer may be deteriorated, since some of the Si—N bonds may not be completely converted into the Si—O bonds, mechanical properties of the silica layer may be deteriorated, and/or out-gassing may occur. When the nitrogen content in the silicon-containing polymer satisfies the described ranges according to example embodiments, etch resistance of the composition for forming a silica layer may be improved.

When the silicon-containing polymer has a weight average molecular weight of about 8,000 g/mol to about 15,000 g/mol according to example embodiments, and simultaneously, the content of nitrogen atoms of the silicon-containing polymer is within the range of about 25 wt % to about 30 wt % based on the total weight of the silicon-containing polymer according to example embodiments, etch resistance of the composition for forming a silica layer may be significantly improved.

According to example embodiments, the silicon-containing polymer may be included at a concentration of about 0.1 wt % to about 30 wt %. For example, the silicon-containing polymer may be included at a concentration of about 0.5 wt % to about 30 wt %, about 1.0 wt % to about 30 wt %, about 1 wt % to about 25 wt %, about 3 wt % to about 25 wt %, about 5 wt % to about 25 wt %, about 10 wt % to about 25 wt %, about 15 wt % to about 25 wt %, about 1 wt % to about 20 wt %, about 3 wt % to about 20 wt %, about 5 wt % to about 20 wt %, about 10 wt % to about 20 wt %, about 20 wt % based on a total amount of the composition for forming a silica layer, but is not limited thereto.

The solvent included in the composition for forming the silica layer is not particularly limited as long as it may dissolve the perhydropolysilazane (PHPS) and does not react with the perhydropolysilazane. For example, the solvent included in the composition for forming the silica layer may include, benzene, toluene, xylene, ethylbenzene, diethylbenzene, trimethylbenzene, triethylbenzene, cyclohexane, cyclohexene, decahydronaphthalene, dipentene, pentane, hexane, heptane, octane, nonane, decane, ethylcyclohexane, methylcyclohexane, p-menthane, dipropylether, dibutylether, anisole, butyl acetate, amyl acetate, methylisobutylketone, or a combination thereof.

The composition for forming a silica layer according to an example embodiment may further include a thermal acid generator (TAG).

The thermal acid generator is an additive to improve developing the composition for forming a silica layer and allows an organosilane-based condensed polymer included in the composition to be developed at a relatively low temperature.

The thermal acid generator may include any compound without particular limit, that generates acid (H⁺) by heat. For example, the compound may include a compound activated at about 90° C. or higher, generating sufficient acid, and having a relatively low volatility.

The thermal acid generator may be, for example, selected from nitrobenzyltosylate, nitrobenzyl benzene sulfonate, phenol sulfonate, and a combination thereof.

The thermal acid generator may be included in an amount of about 0.01 wt % to about 25 wt % based on a total amount of the composition for forming a silica layer. Within the range of about 0.01 wt % to about 25 wt % of the thermal acid generator, the condensed polymer may be developed at a low temperature and simultaneously have improved coating properties.

The composition for forming a silica layer may further include a surfactant.

The surfactant is not particularly limited, and may be, for example, a non-ionic surfactant such as polyoxyethylene alkyl ethers such as polyoxyethylene lauryl ether, polyoxyethylene stearyl ether, polyoxyethylene cetyl ether, polyoxyethylene oleyl ether, and the like, polyoxyethylene alkylallyl ethers such as polyoxyethylenenonyl phenol ether, and the like, polyoxyethylene.polyoxypropylene block copolymers, polyoxyethylene sorbitan fatty acid esters such as sorbitan monolaurate, sorbitan monopalmitate, sorbitan monostearate, sorbitan monoleate, polyoxyethylene sorbitan monostearate, polyoxyethylene sorbitan trioleate, polyoxyethylene sorbitan tristearate, and the like, a fluorine-based surfactant of EFTOP EF301, EF303, EF352 (Tochem Products Co., Ltd.), MEGAFACE F171, F173 (Dainippon Ink & Chem., Inc.), FLUORAD FC430, FC431 (Sumitomo 3M), Asahi guardAG710, Surflon S-382, SC101, SC102, SC103, SC104, SC105, SC106 (Asahi Glass Co., Ltd.), and the like, other silicone-based surfactants such as a organosiloxane polymer KP341 (Shin-Etsu Chemical Co., Ltd.), and the like.

The surfactant may be included in an amount of about 0.001 wt % to about 10 wt % based on the total amount of the composition for forming a silica layer. Within the range of about 0.001 wt % to about 10 wt % of surfactant, dispersion of a solution and simultaneously uniform thickness of a layer may be improved.

According to another example embodiment, a silica layer may be manufactured from the composition for forming a silica layer.

The silica layer may be manufactured by coating the composition for forming a silica layer including a silicon-containing polymer and a solvent according to an example embodiment on a substrate and then curing the composition. For example, the silica layer may be manufactured by a method of manufacturing a silica layer that includes coating the composition for forming a silica layer on the substrate, drying the substrate coated with the composition for forming a silica layer, and curing the resultant under an inert gas atmosphere at greater than or equal to about 150° C.

The composition for forming a silica layer may be coated using a solution process such as, for example, a method such as spin-coating, slit coating, and inkjet printing.

The substrate may be, for example, a device substrate such as a semiconductor, a liquid crystal, and the like, but is not limited thereto.

When the composition for forming a silica layer is completely coated, the substrate may be subsequently dried and cured. The drying and curing may be, for example, performed at greater than or equal to about 100° C. under an atmosphere including inert gas by applying, for example, energy such as heat, ultraviolet (UV), a microwave, a sound wave, an ultrasonic wave, or the like.

For example, the drying may be performed at about 100° C. to about 200° C., and the solvent in the composition for forming a silica layer may be removed by the drying. In addition, the curing may be performed at about 250° C. to about 1,000° C., and through the curing, the layer may be converted into an oxide-like silica thin layer.

The silica layer according to an example embodiment may have significantly improved etch resistance of the layer, and thus, may be advantageously used for, for example, an insulating layer, a filling layer, a protective layer such as a hard coating, a semiconductor capacitor, and the like. The insulating layer may be used, for example, between a transistor element and a bit line, or between a transistor element and a capacitor, but is not limited thereto. Accordingly, according to another example embodiment, an electronic device may include the silica layer according to example embodiments. The electronic device may include a display device, a semiconductor, an image sensor, and the like.

Hereinafter, example embodiments are provided in more detail with reference to examples. However, these examples are exemplary, and the present disclosure is not limited thereto.

### Synthesis Example 1: Preparation of Silicon-Containing Polymer

According to an example embodiment for preparing silicon-containing polymer, the inside of the reactor with a 1 L stirrer and temperature control device is replaced with dry nitrogen. Then, 800 g of dry pyridine is added to the reactor and cooled to −1° C. Then, 60 g of dichlorosilane is injected at a rate of 200 sccm over 65 minutes. After stirring for 1 hour, 37 g of ammonia is injected into the reactor at a rate of 200 sccm over 4 hours. After stirring for 2 hours, dry nitrogen is injected for 12 hours to remove ammonia remaining in the reactor. The obtained white slurry-phase product is filtered under a dry nitrogen atmosphere using a 0.1 μm Teflon (tetrafluoroethylene) filter to obtain 680 g of a filtrate. After adding 800 g of dry xylene, the operation of replacing the solvent from pyridine to xylene using a rotary evaporation concentrator is repeated a total of 3 times to adjust a solid content to 20%, and the resultant is filtered using a Teflon filter having a pore size of 0.1 μm. 100 g of dry pyridine is added to the obtained solution, and polymerization is performed at 100° C. with a solid content of 10% so that the weight average molecular weight is 9,400 g/mol. When the polymerization is completed, the operation of replacing the solvent with dibutyl ether using a rotary evaporator is repeated four times at 70° C. to adjust the solid content concentration to 10%, and is filtered through a 0.1 μm Teflon filter to obtain inorganic polysilazane.

### Synthesis Example 2: Preparation of Silicon-Containing Polymer

According to an example embodiment for preparing silicon-containing polymer, the inside of the reactor with a 1 L stirrer and temperature control device is replaced with dry nitrogen. Then, 800 g of dry pyridine is added to the reactor and cooled to −1° C. Then, 60 g of dichlorosilane is injected at a rate of 200 sccm over 65 minutes. After stirring for 1 hour, 37 g of ammonia is injected into the reactor at a rate of 200 sccm over 4 hours. After stirring for 2 hours, dry nitrogen is injected for 12 hours to remove ammonia remaining in the reactor. The obtained white slurry-phase product is filtered under a dry nitrogen atmosphere using a 0.1 μm Teflon filter to obtain 680 g of a filtrate. After adding 800 g of dry xylene, the operation of replacing the solvent from pyridine to xylene using a rotary evaporation concentrator is repeated a total of 3 times to adjust a solid content to 20%, and the resultant is filtered using a Teflon filter having a pore size of 0.1 μm. 100 g of dry pyridine is added to the obtained solution, and polymerization is performed at 100° C. with a solid content of 10% so that the weight average molecular weight is 10,200 g/mol. When the polymerization is completed, the operation of replacing the solvent with dibutyl ether using a rotary evaporator is repeated four times at 70° C. to adjust the solid content concentration to 10%, and is filtered through a 0.1 μm Teflon filter to obtain inorganic polysilazane.

### Comparative Synthesis Example 1: Preparation of Silicon-Containing Polymer

According to a comparative embodiment of preparing silicon-containing polymer, the inside of the reactor with a 1 L stirrer and temperature control device is replaced with dry nitrogen. Then, 800 g of dry pyridine is added to the reactor and cooled to −1° C. Then, 60 g of dichlorosilane is injected at a rate of 200 sccm over 65 minutes. After stirring for 1 hour, 37 g of ammonia is injected into the reactor at a rate of 200 sccm over 4 hours. After stirring for 2 hours, dry nitrogen is injected for 12 hours to remove ammonia remaining in the reactor. The obtained white slurry-phase product is filtered under a dry nitrogen atmosphere using a 0.1 μm Teflon filter to obtain 680 g of a filtrate. After adding 800 g of dry xylene, the operation of replacing the solvent from pyridine to xylene using a rotary evaporation concentrator is repeated a total of 3 times to adjust a solid content to 20%, and the resultant is filtered using a Teflon filter having a pore size of 0.1 μm. 100 g of dry pyridine is added to the obtained solution, and polymerization is performed at 100° C. with a solid content of 10% so that the weight average molecular weight is 5,400 g/mol. When the polymerization is completed, the operation of replacing the solvent with dibutyl ether using a rotary evaporator is repeated four times at 70° C. to adjust the solid content concentration to 20%, and is filtered through a 0.1 μm Teflon filter to obtain inorganic polysilazane.

### Comparative Synthesis Example 2: Preparation of Silicon-Containing Polymer

According to another comparative embodiment of preparing silicon-containing polymer, the inside of the reactor with a 1 L stirrer and temperature control device is replaced with dry nitrogen. Then, 800 g of dry pyridine is added to the reactor and cooled to −1° C. Then, 60 g of dichlorosilane is injected at a rate of 200 sccm over 65 minutes. After stirring for 1 hour, 37 g of ammonia is injected into the reactor at a rate of 200 sccm over 4 hours. After stirring for 2 hours, dry nitrogen is injected for 12 hours to remove ammonia remaining in the reactor. The obtained white slurry-phase product is filtered under a dry nitrogen atmosphere using a 0.1 μm Teflon filter to obtain 680 g of a filtrate. After adding 800 g of dry xylene, the operation of replacing the solvent from pyridine to xylene using a rotary evaporation concentrator is repeated a total of 3 times to adjust a solid content to 20%, and the resultant is filtered using a Teflon filter having a pore size of 0.1 μm. 100 g of dry pyridine is added to the obtained solution, and polymerization is performed at 100° C. with a solid content of 10% so that the weight average molecular weight is 6,200 g/mol. When the polymerization is completed, the operation of replacing the solvent with dibutyl ether using a rotary evaporator is repeated four times at 70° C. to adjust the solid content concentration to 20%, and is filtered through a 0.1 μm Teflon filter to obtain inorganic polysilazane.

### Comparative Related Synthesis Example 3: Preparation of Silicon-Containing Polymer

According to another comparative embodiment of preparing silicon-containing polymer, the inside of the reactor with a 1 L stirrer and temperature control device is replaced with dry nitrogen. Then, 800 g of dry pyridine is added to the reactor and cooled to −1° C. Then, 60 g of dichlorosilane is injected at a rate of 200 sccm over 65 minutes. After stirring for 1 hour, 37 g of ammonia is injected into the reactor at a rate of 200 sccm over 4 hours. After stirring for 2 hours, dry nitrogen is injected for 12 hours to remove ammonia remaining in the reactor. The obtained white slurry-phase product is filtered under a dry nitrogen atmosphere using a 0.1 μm Teflon filter to obtain 680 g of a filtrate. After adding 800 g of dry xylene, the operation of replacing the solvent from pyridine to xylene using a rotary evaporation concentrator is repeated a total of 3 times to adjust a solid content to 20%, and the resultant is filtered using a Teflon filter having a pore size of 0.1 μm. 100 g of dry pyridine is added to the obtained solution, and polymerization is performed at 100° C. with a solid content of 10% so that the weight average molecular weight is 9,200 g/mol. When the polymerization is completed, the operation of replacing the solvent with dibutyl ether using a rotary evaporator is repeated four times at 70° C. to adjust the solid content concentration to 20%, and is filtered through a 0.1 μm Teflon filter to obtain inorganic polysilazane. The silicon-containing polymers obtained according to Synthesis Examples 1 and 2 and comparative Synthesis Examples 1 to 3 may be adjusted to have a solid concentration of 15% by repetitively substituting the solvent with dibutylether at 70° C. with a rotary evaporator 4 times, and then, filtering with a 0.1 μm Teflon filter to obtain compositions for forming a silica layer according to Examples 1 and 2 and comparative Examples 1 to 3.

The silicon-containing polymers according to Synthesis Examples 1 and 2 and comparative Synthesis Examples 1 to 3 are analyzed with respect to a content of nitrogen atoms through the following steps in a Kjeldahl method using KjelFlex K-360 (BÜCHI Labor Technik AG) and 877 Titrino plus (Metrohm). Initially, a sample (silicon-containing polymer 0.4 g) is prepared. Then, ammonia (NH3) generated by decomposing a sample with a 25% NaOH aqueous solution is collected in a 3% boric acid aqueous solution and then, titrated with a 0.1 N H2SO4 aqueous solution. After the titration, the content of nitrogen atoms is calculated by reflecting a solid content excluding the solvent in the silicon-containing polymers.

The analysis results with weight average molecular weights (Mw) of the silicon-containing polymers are shown in Table 1.

TABLE 1

| | Weight average | |
|---|---|---|
| | molecular weight | Nitrogen content |
| | (g/mol) | (%) |
| Synthesis Example 1 | 9,400 | 27.7 |
| Synthesis Example 2 | 10,200 | 28.3 |
| comparative Synthesis Example 1 | 5,400 | 30.5 |
| comparative Synthesis Example 2 | 6,200 | 29.1 |
| comparative Synthesis Example 3 | 9,200 | 30.2 |

The compositions for forming a silica layer according to Examples 1 and 2 and comparative Examples 1 to 3 are each taken by 3 cc and then, dispensed on the center portion of an 8-inch silicon wafer and spin-coated at 1,500 rpm for 20 seconds with a spin-coater (MS-A200, MIKASA Co., Ltd.). Subsequently, the coated compositions are heated and dried at 150° C. for 3 minutes on a hot plate and then, wet-cured at 800° C. for 60 minutes to form silica layers. Then, thickness changes of the layers while dipped in 1 wt % DHF (diluted hydrofluoric acid) for 10 minutes are measured by using an elliptic spectrometer, M-2000 (J. A. Woollam) and then, compared with the result of a SiO₂ thermal oxide layer formed at 1,000° C. in a wet method, and the relative values (%) thereof are shown in Table 2.

TABLE 2

| | Etch resistance (%) |
|---|---|
| | (relative to that of |
| | SiO₂ thermal oxide layer) |
| Example 1 | 119 |
| Example 2 | 120 |
| comparative Example 1 | 135 |
| comparative Example 2 | 125 |
| comparative Example 3 | 130 |

Referring to Table 2, Examples 1 and 2 including a silicon-containing polymer having a weight average molecular weight of about 8,000 g/mol to about 15,000 g/mol range and a nitrogen content of 25% to 30% based on the weight average molecular weight of the silicon-containing polymer exhibit the closet etch-rate to that of the SiO₂ thermal oxide layer, and thus have significantly improved etching resistance characteristics compared with comparative Examples 1 to 3.

Although example embodiments have been described in detail above, it is not limited to the above example embodiments and may be manufactured in various different forms. Those having an ordinary skill in the art will be able to understand that embodiments can be implemented in other specific forms without changing the technical spirit or essential features and scope as defined by the following claims. Therefore, it should be understood that the example embodiments described above are illustrative and non-limiting in all respects.

What is claimed is:

1. A composition for forming a silica layer comprising
a silicon-containing polymer; and
a solvent,
wherein the silicon-containing polymer has a weight average molecular weight (Mw) of 8,000 g/mol to 15,000 g/mol, and
wherein a content of nitrogen atoms of the silicon-containing polymer measured by a kjeldahl titration method is 25 wt % to 30 wt % based on a total weight of the silicon-containing polymer.

2. The composition of claim 1, wherein the silicon-containing polymer comprises polysilazane, polysiloxazane, or a combination thereof.

3. The composition of claim 1, wherein the silicon-containing polymer is perhydropolysilazane (PHPS).

4. The composition of claim 1, wherein the Mw of the silicon-containing polymer is 8,000 g/mol to 12,000 g/mol.

5. The composition of claim 1, wherein the content of nitrogen atoms of the silicon-containing polymer measured by the kjeldahl titration method is 27 wt % to 29 wt % based on the total weight of the silicon-containing polymer.

6. The composition of claim 1, wherein an amount of the silicon-containing polymer included is 0.1 wt % to 30 wt % based on a total amount of the composition for forming the silica layer.

7. The composition of claim 1, wherein the solvent comprises benzene, toluene, xylene, ethylbenzene, diethylbenzene, trimethylbenzene, triethylbenzene, cyclohexane, cyclohexene, decahydro naphthalene, dipentene, pentane, hexane, heptane, octane, nonane, decane, ethylcyclohexane, methylcyclohexane, cyclohexane, cyclohexene, p-menthane, dipropylether, dibutylether, anisole, butyl acetate, amyl acetate, methylisobutylketone, or a combination thereof.

8. A silica layer formed by a composition, the composition comprising:
a silicon-containing polymer; and
a solvent,
wherein the silicon-containing polymer has a weight average molecular weight (Mw) of 8,000 g/mol to 15,000 g/mol, and
wherein a content of nitrogen atoms of the silicon-containing polymer measured by a kjeldahl titration method is 25 wt % to 30 wt % based on a total weight of the silicon-containing polymer.

9. The silica layer of claim 8, wherein the silicon-containing polymer comprises polysilazane, polysiloxazane, or a combination thereof.

10. The silica layer of claim 8, wherein the silicon-containing polymer is perhydropolysilazane (PHPS).

11. The silica layer of claim 8, wherein the Mw of the silicon-containing polymer is 8,000 g/mol to 12,000 g/mol.

12. The silica layer of claim 8, wherein the content of nitrogen atoms of the silicon-containing polymer measured by the kjeldahl titration method is 27 wt % to 29 wt % based on the total weight of the silicon-containing polymer.

13. The silica layer of claim 8, wherein an amount of the silicon-containing polymer included is 0.1 wt % to 30 wt % based on a total amount of the composition for forming the silica layer.

14. The silica layer of claim 8, wherein the solvent comprises benzene, toluene, xylene, ethylbenzene, diethylbenzene, trimethylbenzene, triethylbenzene, cyclohexane, cyclohexene, decahydro naphthalene, dipentene, pentane, hexane, heptane, octane, nonane, decane, ethylcyclohexane, methylcyclohexane, cyclohexane, cyclohexene, p-menthane, dipropylether, dibutylether, anisole, butyl acetate, amyl acetate, methylisobutylketone, or a combination thereof.

15. An electronic device comprising:
a silica layer formed based on a composition,
wherein the composition comprises:
a silicon-containing polymer; and
a solvent,
wherein the silicon-containing polymer has a weight average molecular weight (Mw) of 8,000 g/mol to 15,000 g/mol, and
wherein a content of nitrogen atoms of the silicon-containing polymer measured by a kjeldahl titration method is 25 wt % to 30 wt % based on a total weight of the silicon-containing polymer.

16. The electronic device of claim 15, wherein the silicon-containing polymer comprises polysilazane, polysiloxazane, or a combination thereof.

17. The electronic device of claim 15, wherein the silicon-containing polymer is perhydropolysilazane (PHPS).

18. The electronic device of claim 15, wherein the Mw of the silicon-containing polymer is 8,000 g/mol to 12,000 g/mol.

19. The electronic device of claim 15, wherein the content of nitrogen atoms of the silicon-containing polymer measured by the kjeldahl titration method is 27 wt % to 29 wt % based on the total weight of the silicon-containing polymer.

20. The electronic device of claim 15, wherein an amount of the silicon-containing polymer included is 0.1 wt % to 30 wt % based on a total amount of the composition for forming the silica layer.
